(19) United States
(12) Patent Application Publication
(10) Pub. No.: US 2011/0294074 A1
(43) Pub. Date: Dec. 1, 2011

(54) EXPOSURE APPARATUS AND EXPOSING METHOD USING THE APPARATUS

(76) Inventors: Ji-Eun LEE, Ansan-si (KR); In-Sung Kim, Suwon-si (KR); Jeong-Ho Yeo, Suwon-si (KR); Chang-Min Park, Hwaseong-si (KR); Je-Bum Yoon, Hwaseong-si (KR)

(21) Appl. No.: 13/149,030

(22) Filed: May 31, 2011

(30) Foreign Application Priority Data
Jun. 1, 2010 (KR) 10-2010-0051965

(51) Int. Cl. G03F 7/20

(52) U.S. Cl. 430/322

(57) ABSTRACT

An exposure apparatus and an exposing method using the apparatus. The exposure apparatus includes a photomask having a plurality of optical sources attached to a substrate.

### CROSS-REFERENCE TO RELATED APPLICATION

This application claims the benefit of Korean Patent Application No. 10-2010-0051965, filed on Jun. 1, 2010, in the Korean Intellectual Property Office, the disclosure of which is incorporated herein in its entirety by reference.

### BACKGROUND

1. Field

The inventive concept relates to an exposure apparatus and an exposing method using the apparatus, and more particularly, to an exposure apparatus required in a photolithography process used to form a semiconductor device and an exposing method using the apparatus.

2. Description of the Related Art

A photolithography process may be used to form a predetermined pattern on a semiconductor substrate. For example, an exposure apparatus may be used to perform an exposure of a photoresist layer on a semiconductor layer, so as to form a photoresist pattern on the semiconductor layer. Such a photoresist pattern may be used, e.g., to etch the semiconductor layer, thereby forming a predetermined pattern on the semiconductor layer (or semiconductor substrate).

In general, an exposure apparatus is a high-priced equipment, and an exposing process performed by such an exposure apparatus constitutes a considerable part of the cost of manufacturing a semiconductor device. Accordingly, an exposure apparatus with lower manufacturing costs and an exposing method using the apparatus may be required.

### SUMMARY

The inventive concept provides an exposure apparatus capable of reducing the cost of manufacturing a semiconductor device.

The inventive concept also provides an exposing method using an exposure apparatus capable of reducing the cost of manufacturing a semiconductor device.

According to an aspect of the inventive concept, there is provided an exposure apparatus including a photomask, wherein the photomask has a plurality of optical sources attached to a substrate.

The apparatus may further include a controller configured to selectively control on/off of each of the plurality of optical sources.

Each of the plurality of optical sources may include a light emitting diode (LED) or a laser diode.

The plurality of optical sources may be arranged in a matrix pattern on the substrate.

The optical sources in the photomask may be configured to perform an exposing process on a wafer.

The apparatus may further include projection optics interposed between the photomask and a wafer, the photomask being configured to perform an exposing process.

The apparatus may further include a resolution improvement unit interposed between the photomask and a wafer, the photomask being configured to perform an exposing process.

The resolution improvement unit may include a plurality of pin holes or lenses in a matrix pattern.

According to another aspect of the inventive concept, there is provided an exposing method using an exposure apparatus, the method including preparing a photomask having a plurality of optical sources attached to a substrate, disposing the photomask on a wafer, irradiating light toward the wafer to perform exposure by selectively controlling on/off of each of the plurality of optical sources, and forming a predetermined pattern on the wafer.

Preparing the photomask may include forming each of the plurality of optical sources as a LED or as a laser diode.

Forming the predetermined pattern may include forming contact hole patterns or through silicon via (TSV) patterns on the wafer. Irradiating the light may include selectively controlling on/off timing of the optical sources, such that optical sources set as “on” correspond to the contact hole patterns or the TSV patterns to be formed in the wafer.

Forming the predetermined pattern may include forming line patterns or space patterns on the wafer. Irradiating the light may include selectively controlling on/off timing of the optical sources, such that optical sources set as “on” correspond to the line patterns or the space patterns to be formed in the wafer, and relatively moving at least one of the photomask and the wafer in a longitudinal direction of the line patterns or the space patterns.

Forming the predetermined pattern may include forming line or space patterns having different widths. Irradiating the light may include selectively controlling on/off timing of the optical sources, such that optical sources set as “on” correspond to the line or space patterns to be formed in the wafer, and such that a larger number of optical sources corresponds to a wider pattern, and relatively moving at least one of the photomask and the wafer in a longitudinal direction of the line or space patterns.

Irradiating the light may include controlling the on/off of each of the optical sources of the photomask to correspond to the predetermined pattern on the wafer, and relatively moving at least one of the photomask and the wafer. The relative moving may include at least one of a stepping method, a global scanning method, or a micro scanning method. Controlling the on/off of the optical sources may include shifting defective optical sources to align operational optical sources with the predetermined pattern.

According to another aspect of the inventive concept, there is provided an exposing method using an exposure apparatus, the method including preparing a photomask including a plurality of optical sources on a substrate, disposing the photomask relative to a wafer, such that light from the photomask is incident on the wafer, and selectively controlling light emission of each of the plurality of optical sources, such that light emitted from the photomask is incident only on regions of the wafer to be patterned.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a conceptual view of a general exposure apparatus illustrated for comparison with an exposure apparatus according to an embodiment;

FIG. 2 illustrates a cross-sectional view of an exposure apparatus according to an embodiment;

FIG. 3 illustrates a plan view of an upper surface of the exposure apparatus of FIG. 2;

FIG. 4 illustrates a cross-sectional view of an exposing process performed on a wafer by using the exposure apparatus of FIG. 2;

FIG. 5 illustrates a cross-sectional view of an exposing process performed on a wafer by using an exposure apparatus according to another embodiment;

FIG. 6 illustrates a cross-sectional view of an exposing process performed on a wafer by using an exposure apparatus according to another embodiment;

FIGS. 7 and 8 illustrate cross-sectional views of resolution improvement units accompanied with exposure apparatuses according to other embodiments;

FIG. 9 illustrates a plan view of contact hole patterns or through silicon via patterns to be formed on a wafer;

FIGS. 10 through 15 illustrate plan views of stages in an exposing method used to form the patterns illustrated in FIG. 9;

FIG. 16 illustrates a plan view of line patterns or space patterns to be formed on a wafer;

FIGS. 17 and 18 illustrate plan views of stages in an exposing method used to form the patterns illustrated in FIG. 16;

FIG. 19 illustrates a plan view of a line pattern or a space pattern to be formed on a wafer;

FIGS. 20 through 21 illustrate plan views of stages in an exposing method used to form the patterns illustrated in FIG. 19;

FIG. 22 illustrates a plan view of line patterns to be formed on a wafer during an intermediate stage of a dual exposing process;

FIG. 24 illustrates a plan view of contact hole patterns to be formed on a wafer during a dual exposing process;

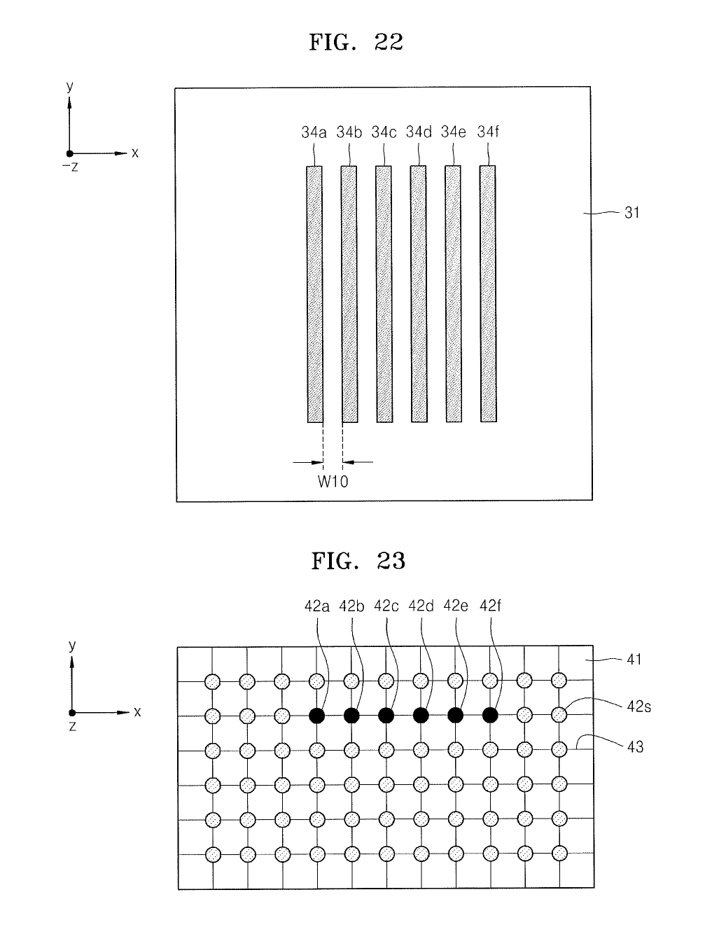

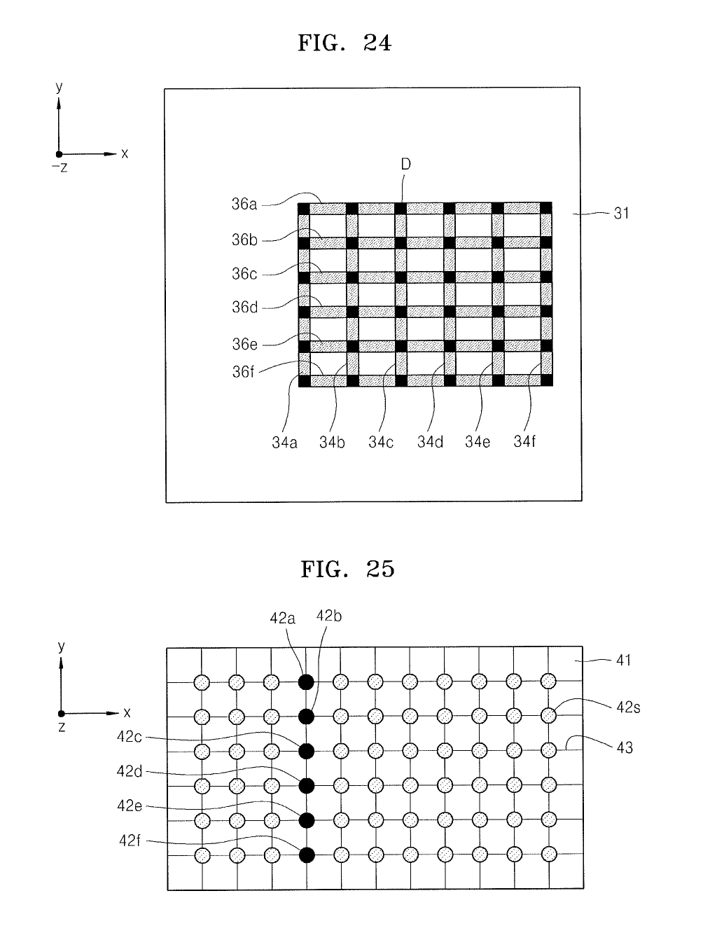

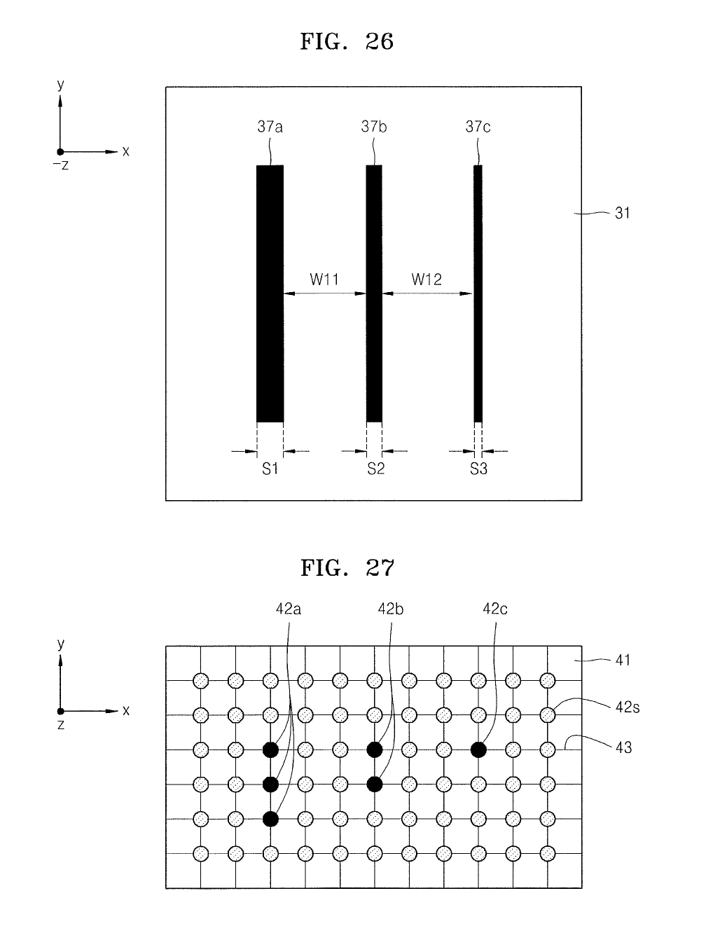

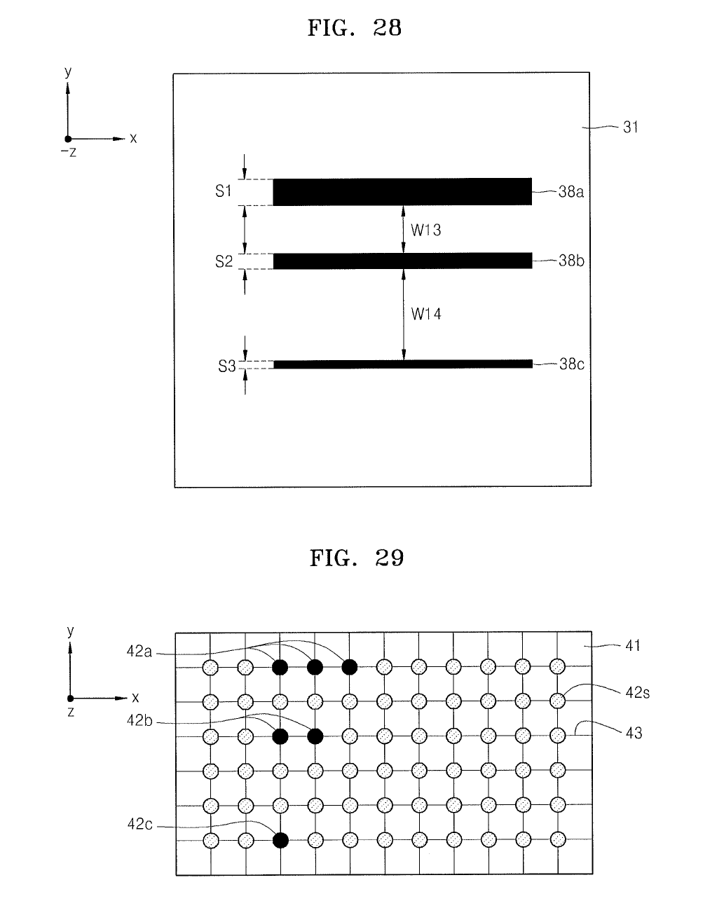

FIGS. 23 and 25 illustrate plan views of stages in an exposing method used to form the patterns of FIGS. 22 and 24, respectively;

FIG. 26 illustrate a plan view of line patterns or space patterns to be vertically formed on a wafer;

FIG. 27 illustrates a plan view of an exposing method used to form the pattern of FIG. 26;

FIG. 28 illustrates a plan view of line patterns or space patterns to be horizontally formed on a wafer; and

FIG. 29 illustrates a plan view of an exposing method used to form the pattern of FIG. 28.

### DETAILED DESCRIPTION

Hereinafter, embodiments of the inventive concept will be described more fully with reference to the accompanying drawings. In the drawings, like reference numerals denote like elements. The inventive concept may, however, be embodied in many different forms and should not be construed as being limited to the embodiments set forth herein; rather, these embodiments are provided so that this disclosure will be thorough and complete, and will fully convey the concept of the invention to those of ordinary skill in the art. In the drawings, the sizes of elements may be exaggerated for clarity. In particular, the size of an optical source body attached to a substrate may be exaggerated for clarity, regardless of a relative size ratio.

Throughout the specification, it will be understood that when an element such as a layer, an area, or a substrate is referred to as being “on” another element or “between” elements, it can be directly or indirectly on the other element or between elements. That is, intervening elements may be present. In contrast, when an element is referred to as being “directly on” another element, there are no intervening elements or layers present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The term “layer” used herein is used to refer to a part of a structure generated when materials are stacked upon one another. Accordingly, the term “layer” should not be limited to a thickness of materials.

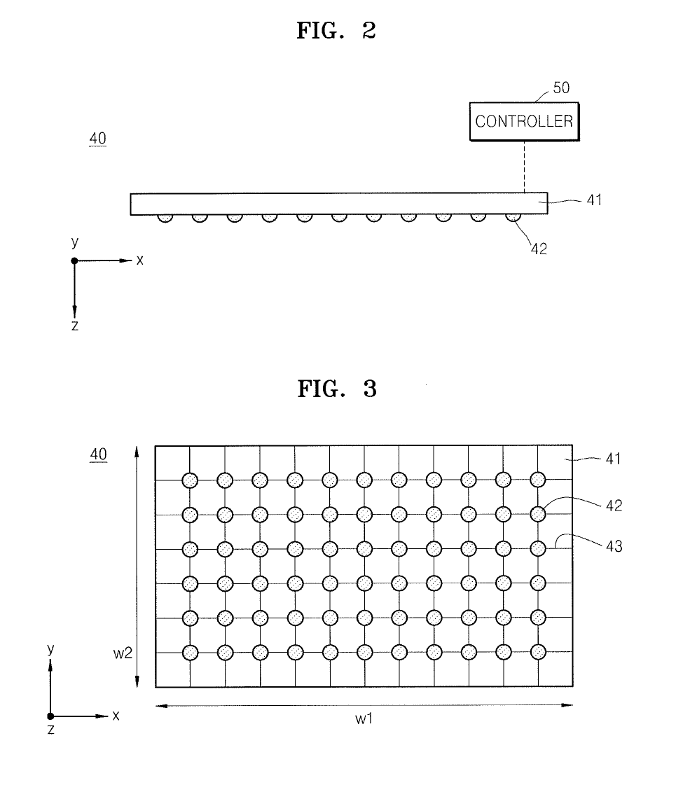

FIG. 2 illustrates a cross-sectional view of an exposure apparatus according to an embodiment, and FIG. 3 illustrates a plan view of an upper surface of the exposure apparatus of FIG. 2.

In a coordinate axis illustrated in FIG. 2, an x-axis direction is a right horizontal direction, a z-axis direction is a downward direction, and a y-axis direction is directed from the cross-section area toward an observer. In a coordinate axis illustrated in FIG. 3, an x-axis direction is a right horizontal direction, a y-axis direction is an upward direction, and a z-axis direction is directed from the cross-section area toward an observer. Such definitions of the coordinates are the same for all drawings.

Referring to FIGS. 2 and 3, an exposure apparatus according to an example embodiment includes a photomask 40. The photomask 40 may include a substrate 41 and a plurality of optical sources 42 on, e.g., attached to, the substrate 41. For example, the plurality of optical sources 42 may be attached to a same surface of the substrate 41, and may be spaced apart from each other. For example, distances between adjacent optical sources 42 and their relative arrangement on the substrate 41 may be adjusted, as will be discussed in more detail below.

The substrate 41 may include a transparent material. For example, the substrate 41 may be a glass substrate including quartz.

The plurality of optical sources 42 may each include a light emitting diode (LED) or a laser diode. Both the LED and the laser diode emit light by using an electro-luminescence phenomenon by which light is emitted when a p-type semiconductor and an n-type semiconductor are bonded together, and then a current flows.

More specifically, in the LED, when a p-type semiconductor and an n-type semiconductor are bonded together, and then a positive voltage is applied to the p-type semiconductor so as to remove electrons and form holes, and a negative voltage is applied to the n-type semiconductor and electrons are injected into the n-type semiconductor, the holes and electrons are diffused and combined at a bonded surface, thereby emitting light. In general, compound semiconductors formed of Group 13 (Group 3A) elements, e.g., Al, Ga, or In, and of Group 15 (Group 5A) elements, e.g., P or As, of the periodic table are used, and the color of the light varies according to the compounds. Light emitted from the LED may be, for example, a mixture light having various wavelengths, and is emitted in a radial manner based on a luminous body. Currently, high-output UV LEDs having a peak at a main wavelength of 365 nm and using a mercury lamp have been developed, and such a high-output UV LED may be used as the optical source 42.

In the laser diode, light having one specific wavelength, i.e., a monochromatic beam, are emitted at a same phase and in a same direction by using stimulated emission and constructive interference. The LED emits incoherent light, whereas the laser diode emits coherent light.

Referring back to FIGS. 2-3, operation, i.e., on/off function, of each of the plurality of optical sources 42 may be selectively, e.g., and independently, controlled. A controller 50 may be included in the exposure apparatus according to the current embodiment in order to selectively control on/off of each of the plurality of optical sources 42. The controller 50 may be electrically connected to the photomask 40, and may be on, e.g., physically attached to, the photomask 40. However, the inventive concept is not limited thereto and the controller 50 may be spaced apart from the photomask 40. The plurality of optical sources 42 may be each connected to the controller 50 by a connection member 43.

For example, any number of the plurality of optical sources 42 may be arranged on the substrate 41 in a predetermined pattern, e.g., in a matrix pattern. For example, the plurality of optical sources 42 may be arranged in a matrix pattern to overlap a majority of a surface area of a wafer to be processed, thereby covering different regions of the wafer, i.e., different regions of a subsequently formed semiconductor device. For example, m×n (m and n are positive numbers) optical sources 42 may be disposed in a matrix pattern on the substrate 41. In the plurality of optical sources 42, m and n may be arbitrary positive numbers. For example, as illustrated in FIG. 3, m may be 11 and n may be 6.

The size of the substrate 41 on which the plurality of optical sources 42 are disposed may be determined according to system conditions. For example, a length W1 of the substrate 41, e.g., along the x-axis, may be 26 mm, and a width W2 of the substrate 41, e.g., along the y-axis, may be 8 mm.

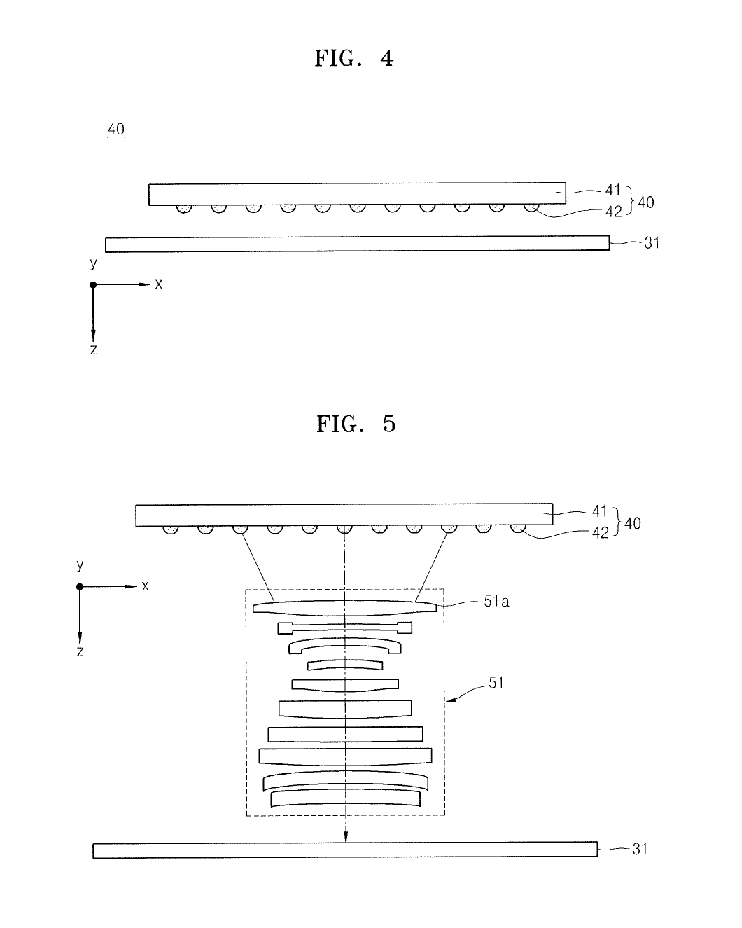

The exposure apparatus uses the photomask 40 in order to perform an exposing process on a wafer, as will be discussed in more detail below with reference to FIG. 4. FIG. 4 illustrates a cross-sectional view of an exposing process performed on a wafer 31 by using the exposure apparatus of FIG. 2 according to an embodiment.

Referring to FIG. 4, the photomask 40 including the substrate 41 and the plurality of optical sources 42 attached to the substrate 41 may be prepared, and may be disposed above the wafer 31. As illustrated in FIG. 4, the photomask 40 may be arranged, so the optical sources 42 face the wafer 31. For example, the optical sources 42 may overlap a majority of the wafer 31.

The wafer 31 may include any substrate that is well known to one of ordinary skill in the art in a semiconductor manufacturing process, e.g., a substrate including semiconductor silicon. A thin photoresist layer (not illustrated) may be formed on the wafer 31, and an exposing process may be performed on the thin photoresist layer by the photomask 40. Then, when a developing process is performed, the photoresist layer may be formed into a predetermined photoresist layer pattern. A lower layer (not illustrated) may be etched by using the photoresist layer pattern as a mask film, thereby forming a predetermined pattern on the wafer 31.

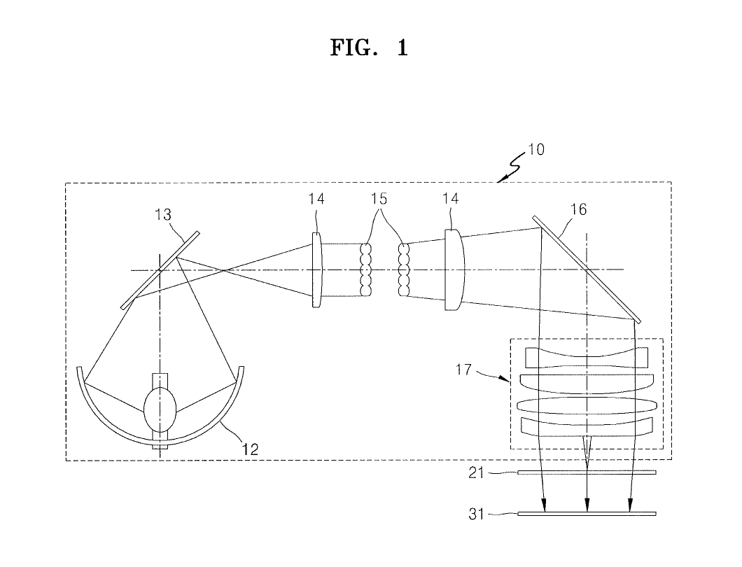

An optical source may be needed to perform the exposing process on the photoresist layer. As described previously, the optical source of the exposure system may be the plurality of optical sources 42 of the photomask 40. That is, on/off of each of the plurality of optical sources 42 may be selectively controlled, thereby irradiating light for exposure to the wafer 31. For example, each of the plurality of optical sources 42 may be independently controlled to be turned on/off in order to irradiate light onto different regions of the substrate 31. For example, as the matrix pattern of the plurality of optical sources 42 may be arranged in any shape relative to the wafer 31, e.g., the matrix pattern of the plurality of optical sources 42 may be arranged to overlap a majority of a surface area of the wafer 31, and as distances between the plurality of optical sources 42 along the x and y axes may be controlled, e.g., to be very small, irradiation coverage of the wafer 31 may be improved, e.g., without a need for multiple masks to process different regions and layers of the wafer 31, and irradiation precision of high integration patterns may be increased. Further, use of the plurality of optical sources 42, e.g., instead of using an expensive optical system with lenses and mirrors, may reduce manufacturing costs, as will be explained in more detail below with reference to FIG. 1.

FIG. 1 illustrates a conceptual view of a comparative exposure apparatus 10 performing an exposing process on the wafer 31. Referring to FIG. 1, an illumination optic system 10 includes an extra-high pressure mercury lamp 12, a return mirror 13, a collimation mirror 14, fly-eye lenses 15, a return mirror 16, and a condenser lens unit 17. An optical source used in the illumination optic system 10 of FIG. 1 is the extra-high pressure mercury lamp 12, so light emitted from the extra-high pressure mercury lamp 12 is irradiated to a photomask 21 by using various mirrors and lenses therebetween. That is, the illumination optic system 10 includes a complex arrangement of mirrors and lenses, e.g., the return mirror 13, the collimation mirror 14, the fly-eye lenses 15, the return mirror 16, and the condenser lens unit 17, in order to irradiate light with uniform distribution toward the photomask 21.

The photomask 21 includes an opaque pattern on a transparent substrate, so light irradiated from the extra-high pressure mercury lamp 12 onto the photomask 21 is partially and selectively transmitted through the transparent substrate, thereby performing the exposing process on the wafer 31.

The comparative illumination optic system 10 requires high-priced installation and maintenance costs, which constitute a considerable part of the costs of manufacturing a semiconductor device. Also, the photomask 21 may be required to be separately formed on each layer of a semiconductor device, thereby increasing costs of manufacturing a semiconductor device further. In addition, when a pattern to be formed on the wafer 31 is a contact hole, only about 1% of energy generated by the extra-high pressure mercury lamp 12 of the comparative illumination optic system 10 reaches the wafer 31, thereby generating a high energy loss.

Therefore, the exposure apparatus according to example embodiments may include the photomask 40 with the optical sources 42 attached to the substrate 41, so a need for a separate illumination optic system, e.g., the illumination optic system 10 including a plurality of lenses and mirrors of FIG. 1, may be eliminated, thereby substantially reducing manufacturing costs of semiconductor devices. Further, as the optical sources 42 in the photomask are disposed in a matrix pattern on the substrate 41, and each of the optical sources 42 may be selectively controlled, a separate photomask may not be required on each layer of a semiconductor layer, e.g., as compared to the illumination optic system 10.

For example, when a pattern to be formed on the wafer 31 is a through silicon via (TSV) pattern, the exposure apparatus according to the current embodiment may be efficiently applied. In detail, as a size of a TSV pattern is relatively large, the CD (critical dimension) management may be relatively easy. Accordingly, the exposure apparatus according to the current embodiment may be used to easily form the TSV pattern on the wafer 31 via control, i.e., control of on/off operation, of the plurality of the optical sources 42 on the substrate 41, so a high-priced illumination optic system with separate photomasks is not required.

FIG. 5 illustrates a cross-sectional view of an exposing process performed on the wafer 31 by using an exposure apparatus according to another embodiment. Referring to FIG. 5, an exposure apparatus according to the current embodiment may be substantially the same as that of FIGS. 2-3, with the exception of further including projection optics 51 interposed between the photomask 40 and the wafer 31.

In detail, the projection optics 51 may include a plurality of optical devices 51a. The projection optics 51 may be needed when the resolution of the wafer 31 is higher than an array resolution of the plurality of optical sources 42.

That is, in the exposure apparatus of FIGS. 2-4, a pattern may be formed on the wafer 31 by direct 1× magnification exposure. However, when the resolution of the wafer 31 is higher than the array resolution of the plurality of optical sources 42, the exposure apparatus of FIG. 5 may be used.

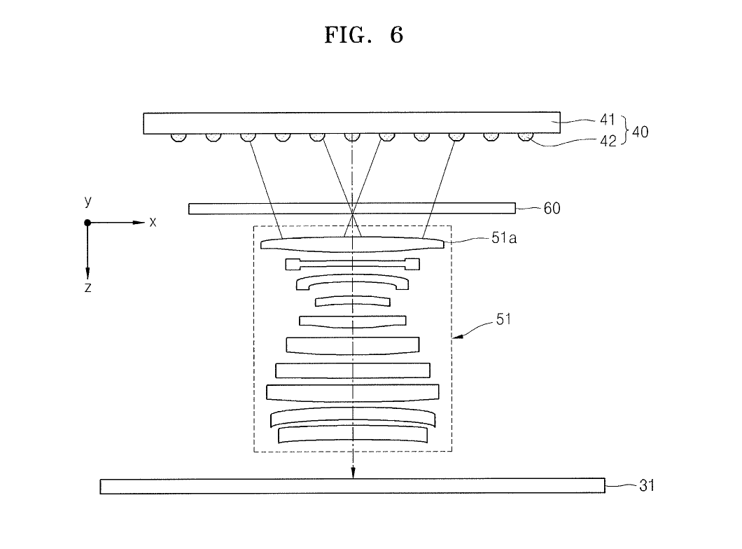

FIG. 6 illustrates a cross-sectional view of an exposing process performed on the wafer 31 according to another embodiment. Referring to FIG. 6, an exposure apparatus according to the current embodiment may be substantially the same as that of FIG. 5, with the exception of further including a resolution improvement unit 60 interposed between the photomask 40 and the wafer 31. The resolution improvement unit 60 is needed when integration of a pattern formed on the wafer 31 is high, i.e., the resolution improvement unit 60 reduces the size of a beam of light emitted from the plurality of optical sources 42 of the photomask 40 or improves convergence of light.

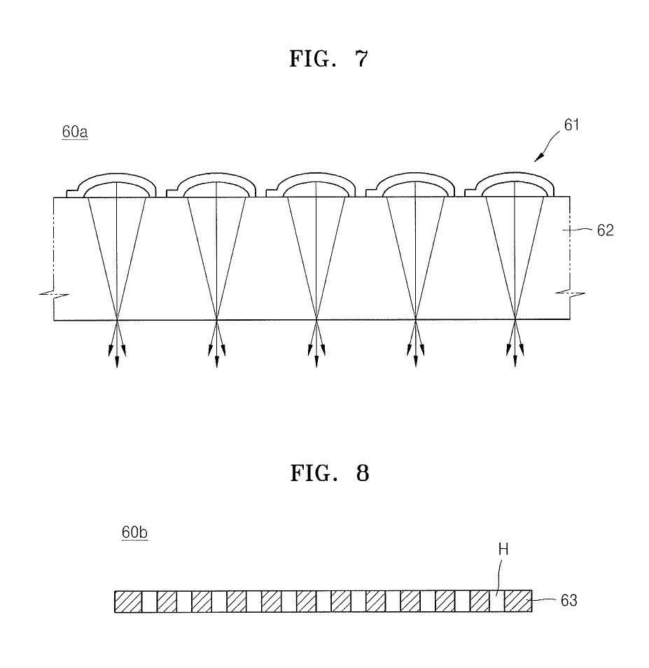

For example, the resolution improvement unit 60 may include a plurality of pin holes arranged in an array form or a plurality of lenses arranged in an array form. Examples of resolution improvement units 60a and 60b will be explained in more detail below with reference to FIGS. 7 and 8, respectively.

Referring to FIG. 7, the resolution improvement unit 60a in an exposure apparatus according to the current embodiment may include a substrate 62 and a plurality of lenses 61 arranged in a matrix pattern, e.g., an array form, on the substrate 62. Convergence of light emitted by the plurality of optical sources 42 may be improved due to the resolution improvement unit 60a including the plurality of lenses 61 arranged in a matrix pattern. Thus, a fine pattern may be formed on the wafer 31.

Referring to FIG. 8, the resolution improvement unit 60b in an exposure apparatus according to the current embodiment may include a substrate 63 and a plurality of pin holes H arranged in a matrix pattern, e.g., an array form, on the substrate 63. The size of a beam of light emitted by the plurality of optical sources 42 may be reduced due to the resolution improvement unit 60b including the plurality of pin holes H arranged in a matrix pattern. Thus, a fine pattern may be formed on the wafer 31.

As described above, the exposure apparatuses according to various embodiments are described. Hereinafter, exposing methods using the exposure apparatuses will be described.

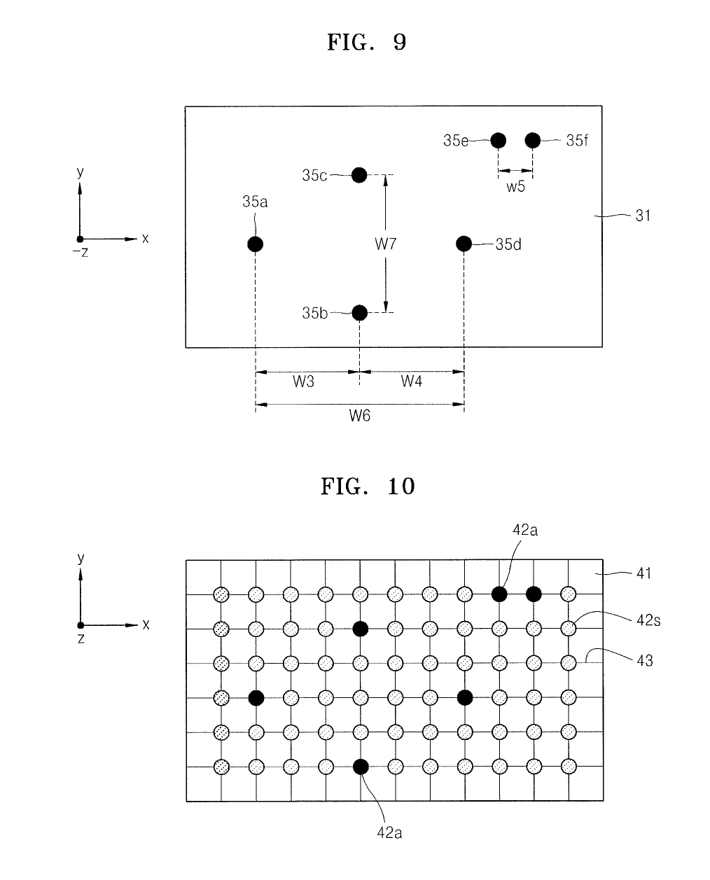

FIG. 9 illustrates a plan view of first through sixth TSV patterns 35a through 35f to be formed on the wafer 31, and FIGS. 10 through 15 illustrate plan views of exposing methods used to form the patterns illustrated in FIG. 9. It is noted that even though elements 35a through 35f, as well as the description hereinafter, refer to TSV patterns, same methods may be used to form contact hole patterns. In particular, the TSV patterns are widely used in a process of manufacturing a wafer level package and are similar to the contact hole patterns in that holes are formed in a height direction of a semiconductor substrate. However, the TSV patterns are larger than general contact hole patterns and separation distances between the patterns are also greater.

Referring to FIG. 9, the first through sixth TSV patterns 35a through 35f may be formed on the wafer 31 at predetermined distances. For example, the first TSV pattern 35a and the second TSV pattern 35b may be formed with a third distance W3 therebetween, the second TSV pattern 35b and the fourth TSV pattern 35d may be formed with a fourth distance W4 therebetween, the fifth TSV pattern 35e and the sixth TSV pattern 35f may be formed with a fifth distance W5 therebetween, the first TSV pattern 35a and the fourth TSV pattern 35d may be formed with a sixth distance W6 therebetween, and the second TSV pattern 35b and the third TSV pattern 35c may be formed with a seventh distance W7 therebetween. The third through seventh distances W3 through W7 between the different first through sixth TSV patterns 35a through 35f may each be smaller than the first and second distances W1 and W2 of the substrate 41 (length and width in FIG. 3). Once the configuration of the TSV patterns with the distances therebetween is determined and noted, the photomask 40 and the wafer 31 may be arranged according to FIG. 4.

Next, referring to FIG. 10, the photomask 40 and/or the wafer 31 may not be relatively moved, i.e., may remain stationary, and exposure may occur only by controlling operation of the optical sources 42 on the substrate 41 in order to irradiate light toward predetermined regions of the wafer 31. That is, predetermined optical sources 42a among the plurality of optical sources 42, e.g., six optical sources positioned directly above respective noted locations of the first through sixth TSV patterns 35a through 35f, may be selectively controlled to irradiate light and perform exposure of the predetermined regions of the wafer 31 to subsequently form the first through sixth TSV patterns 35a through 35f. As discussed previously, the optical sources 42a that are controlled in terms of on/off correspond to the first through sixth TSV patterns 35a through 35f, i.e., the optical sources 42a may simultaneously or sequentially be turned “on” and remaining optical sources 42s may be “off”. On/off of the plurality of optical sources 42 may be applied in an opposite way according to the type of photoresist layer coated on the wafer 31.

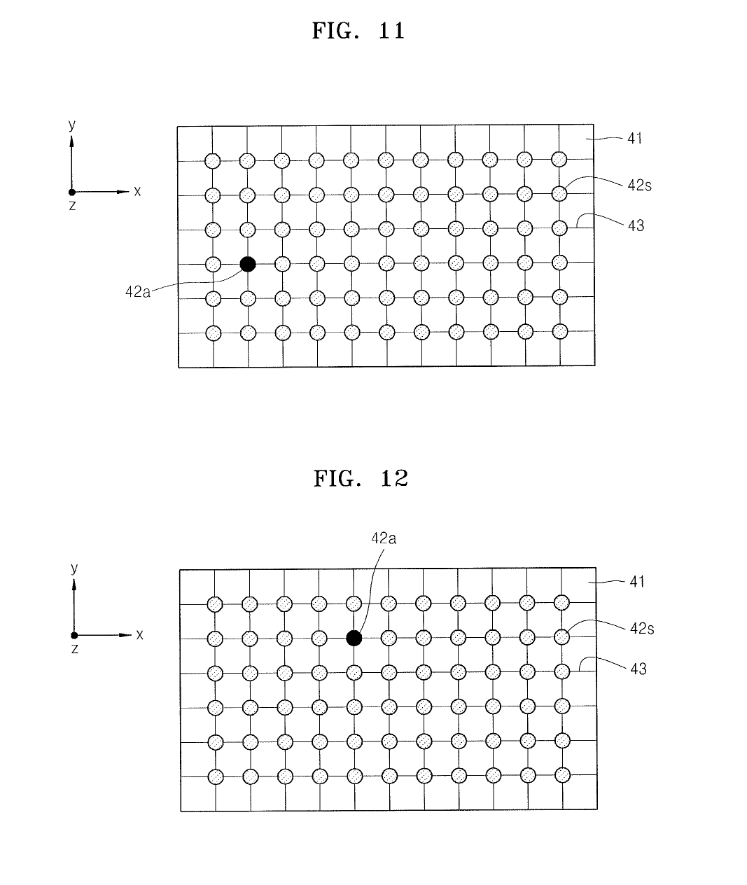

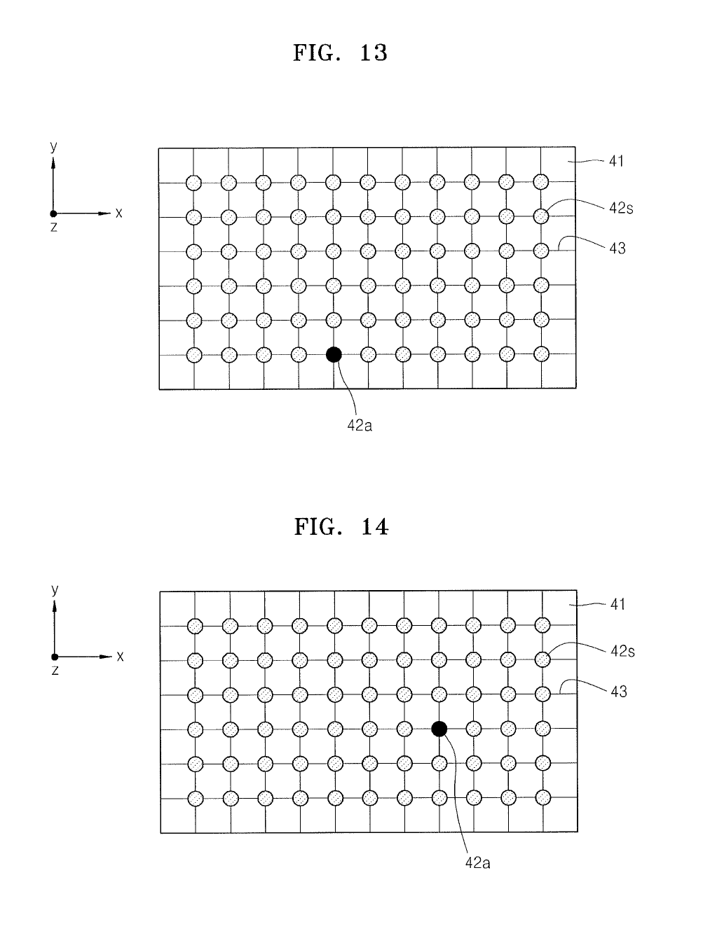

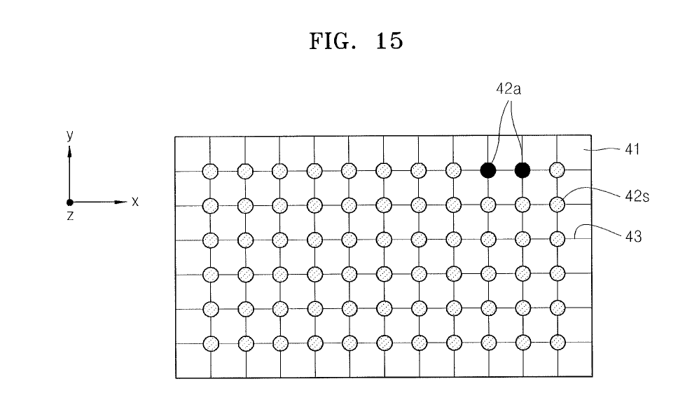

Referring to FIG. 9 and FIGS. 11-15, when some distances between the first through sixth TSV patterns 35a through 35f are larger than the first and second distances W1 and W2 of the substrate 41 of the photomask 40, e.g., distances W3-W4 and W6-W7, the photomask 40 and/or the wafer 31 may be adjusted between operation of different optical sources 42. For example, on/off of only the optical source 42a of FIG. 11 disposed to correspond to the first TSV pattern 35a from among the plurality of optical sources 42 is selectively controlled to irradiated light onto the wafer 31. Then, one or both of the photomask 40 and the wafer 31 may be relatively and appropriately moved, followed by selectively controlling on/off of only the optical source 42a of FIG. 12 disposed to correspond to the third TSV pattern 35c from among the plurality of optical sources 42 to irradiate light. Then, one or both of the photomask 40 and the wafer 31 may be relatively and appropriately moved, followed by selectively controlling on/off of only the optical source 42a of FIG. 13 disposed to correspond to the second TSV pattern 35b from among the plurality of optical sources to irradiate light. Then, one or both of the photomask 40 and the wafer 31 may be relatively and appropriately moved, followed by selectively controlling on/off of only the optical source 42a of FIG. 14 disposed to correspond to the fourth TSV pattern 35d from among the plurality of optical sources 42 to irradiate light. Finally, one or both of the photomask 40 and the wafer 31 may be relatively and appropriately moved, followed by selectively, e.g., and simultaneously, controlling on/off of only the optical source 42a of FIG. 15 disposed to correspond to the fifth TSV pattern 35e and the sixth TSV pattern 35f from among the plurality of optical sources 42 to irradiate light.

When the type of the photoresist layer coated on the wafer 31 is a positive type, only optical sources 42a of FIGS. 10 to 15 disposed to correspond to the TSV patterns 35a through 35f from among the plurality of optical sources 42 are selectively “on” and the remaining optical sources 42s are selectively “off”, thereby performing an exposing process. However, when the type of the photoresist layer coated on the wafer 31 is a negative type, only optical sources 42a of FIGS. 10 to 15 disposed to correspond to the first through sixth TSV patterns 35a through 35f from among the plurality of optical sources 42 are selectively off and the remaining optical sources 42s are selectively “on”, thereby performing an exposing process.

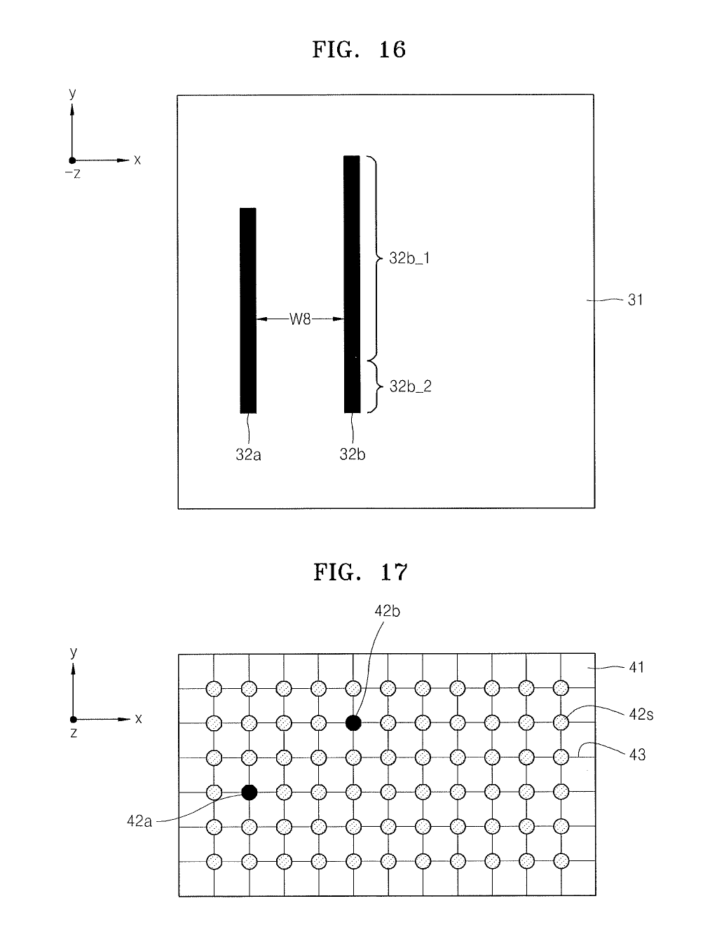

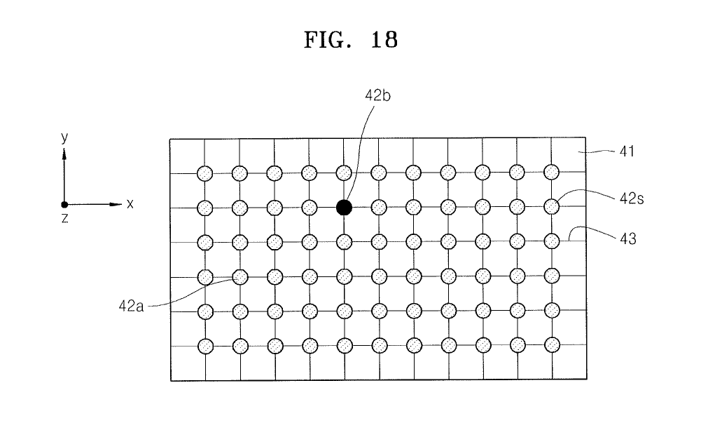

FIG. 16 illustrates a plan view of first and second line patterns 32a and 32b (or space patterns) to be formed on the wafer 31. FIGS. 17 and 18 illustrate plan views of exposing methods used to form the patterns in FIG. 16.

Referring to FIG. 16, the first and second line patterns 32a and 32b to be vertically formed on the wafer 31 are illustrated. However, the patterns are not limited to the line patterns and the patterns to be formed in a longitudinal direction may be space patterns. The line patterns may be widely used in a process of manufacturing a semiconductor e.g., word line patterns, bit line patterns, wiring line patterns, etc.

The first line pattern 32a and the second line pattern 32b may be spaced apart from each other by a predetermined eighth distance W8. The second line pattern 32b may be longer than the first line pattern 32a by a predetermined length 32b_2.

Referring to FIGS. 16 and 17, when the distance, e.g., the eighth distance W8, between the first line pattern 32a and the second line pattern 32b is smaller than the width of the substrate 41 of the photomask 40, e.g., the first width W1 in FIG. 3, the optical source 42a of FIG. 17 disposed to correspond to the upper most part of the first line pattern 32a in the y-axis direction and the optical source 42b of FIG. 17 disposed to correspond to the upper most part of the second line pattern 32b in the y-axis direction are selectively controlled to be “on”, and the remaining optical sources 42s are controlled to be “off”. Then, one or both of the photomask 40 and the wafer 31 may be relatively and appropriately moved in the longitudinal direction (along the ±y-axis direction in FIG. 16) of the first and second line patterns 32a and 32b, while the optical sources 42a and 42b may remain “on”. For example, while the optical source 42a of FIG. 17 disposed to correspond to the upper most part of the first line pattern 32a in the y-axis direction and the optical source 42b of FIG. 17 disposed to correspond to the upper most part of the second line pattern 32b in the y-axis direction are selectively controlled to be “on” and the remaining optical sources 42s are controlled to be “off”, the photomask 40 may be appropriately moved in the longitudinal direction (in FIG. 16, −y direction) of the first and second line patterns 32a and 32b on the wafer 31. When the photomask 40 is moved so as to complete the first line pattern 32a, e.g., when the photomasks 40 is moved along the y-axis a distance that equals a length of the first line pattern 32a, while the optical source 42a of FIG. 17 is controlled to be on, the optical source 42b of FIG. 17 controlled to be “on” forms only a part 32b_1 of the second line pattern 32b. Accordingly, in order to form a remaining part 32b_2 of the second line pattern 32b, the optical source 42a of FIG. 18 is controlled to be “off” and the optical source 42b of FIG. 18 is controlled to be “on”. Then, the photomask 40 is moved in the longitudinal direction (in FIG. 16, −y direction) of the first and second line patterns 32a and 32b on the wafer 31. In this case, the remaining optical sources 42s are controlled to be “off” similarly to the optical source 42a.

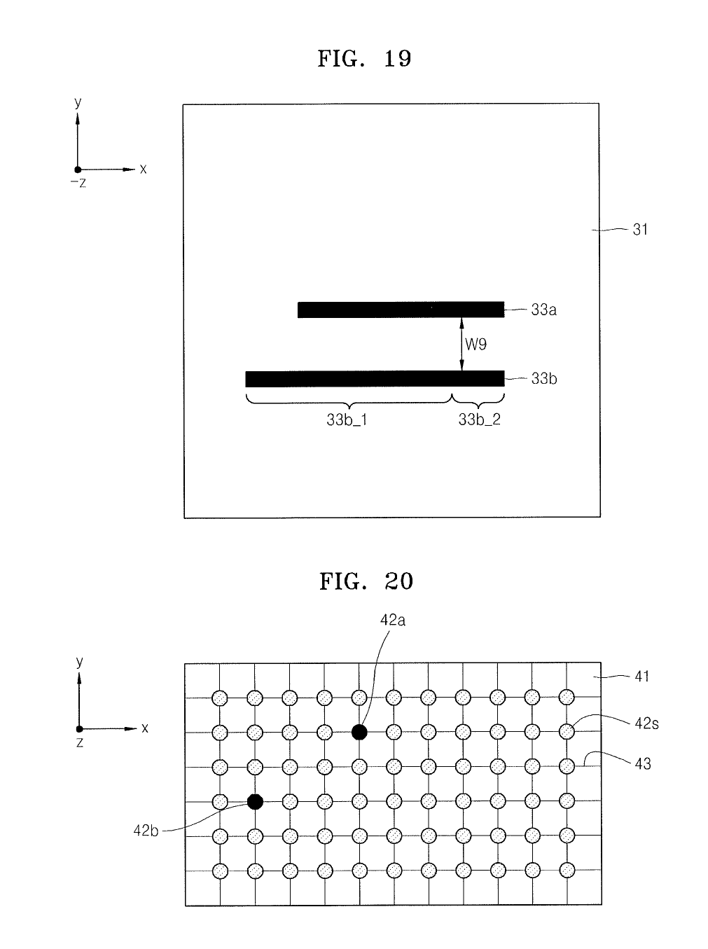

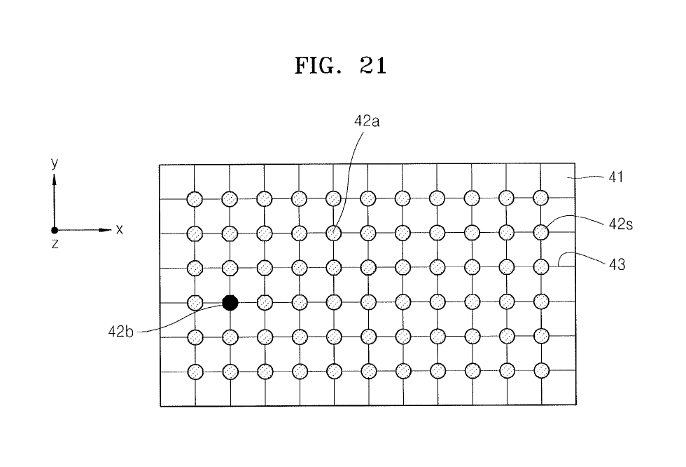

FIG. 19 illustrates a plan view of first and second line patterns 33a and 33b (or space patterns) to be formed on the wafer 31. FIGS. 20 through 21 illustrate plan views of exposing methods used to form the patterns illustrated in FIG. 19.

Referring to FIG. 19, the first and second line patterns 33a and 33b to be horizontally formed on the wafer 31 are illustrated. However, the patterns are not limited to the line patterns, and the patterns to be formed in a longitudinal direction may be space patterns. The line patterns are widely used in a process of manufacturing a semiconductor device and may be used in, e.g., word line patterns, bit line patterns, and wiring line patterns.

The first line pattern 33a and the second line pattern 32b are spaced apart from each other by a predetermined distance W9. The second line pattern 33b may be longer than the first line pattern 33a by a predetermined length 33b_2.

Referring to FIGS. 19 and 20, when the distance (for example, W9) between the first line pattern 33a and the second line pattern 33b is smaller than the width (for example, W2 of FIG. 3) of the substrate 41 of the photomask 40 to which the plurality of optical sources 42 are attached, the optical source 42a of FIG. 20 disposed to correspond to the left end of the first line pattern 33a in the x-axis direction, and the optical source 42b of FIG. 20 disposed to correspond to the left end of the second line pattern 33b in the x-axis direction are selectively controlled to be “on”, and the remaining optical sources 42s are controlled to be “off”. Then, one or both of the photomask 40 and the wafer 31 may be relatively and appropriately moved in the longitudinal direction (in FIG. 19, +x direction) of the first and second line patterns 33a and 33b. For example, while the optical source 42a of FIG. 20 disposed to correspond to the left end of the first line pattern 33a in the x-axis direction, and the optical source 42b of FIG. 20 disposed to correspond to the left end of the second line pattern 33b in the x-axis direction are selectively controlled to be “on” and the remaining optical sources 42s are controlled to be “off”, the photomask 40 may be appropriately moved in the longitudinal direction (in FIG. 19, x-axis direction) of the first and second line patterns 33a and 33b on the wafer 31. When the photomask 40 is moved so as to complete the first line pattern 33a while the optical source 42a of FIG. 20 is controlled to be “on”, the optical source 42b of FIG. 19 controlled to be “on” forms only a part 33b_1 of the second line pattern 33b. Accordingly, in order to form a remaining part 33b_2 of the second line pattern 33b, the optical source 42a of FIG. 21 is controlled to be “off” and the optical source 42b of FIG. 21 is controlled to be “on”. Then, the photomask 40 is moved in the longitudinal direction (in FIG. 19, x-axis direction) of the first and second line patterns 33a and 33b on the wafer 31. In this case, the remaining optical sources 42s are controlled to be “off” similarly to the optical source 42a.

FIG. 24 illustrates a plan view of contact hole patterns to be formed on the wafer during a dual exposing process, FIG. 22 illustrates a plan view of a plurality of line patterns 34a, 34b, 34c, 34d, 34e, and 34f to be formed on the wafer 31 during an intermediate stage of a dual exposing process, and FIGS. 23 and 25 illustrate plan views of exposing methods used to form the patterns of FIGS. 22 and 24, respectively.

Referring to FIG. 22, the plurality of line patterns 34a, 34b, 34c, 34d, 34e, and 34f to be vertically formed on the wafer 31 are illustrated. However, the patterns are not limited to the line patterns, e.g., the patterns to be formed in a longitudinal direction may be space patterns. It is noted that in the current embodiment, the line patterns are not formed on the wafer 31 vertically, but instead, contact hole patterns are to formed at parts where line patterns in a horizontal direction and line patterns in a vertical direction cross each other, as illustrated in FIG. 24.

When a distance W10 between the plurality of line patterns 34a through 34f is smaller than the width of the substrate 41 of the photomask 40, e.g., the first width W1 of FIG. 3, optical sources 42a through 42f of FIG. 23 disposed to correspond to the upper most part of the plurality of line patterns 34a through 34f in the y-axis direction are controlled to be “on” and the remaining optical sources 42s are controlled to be “off”. Then, one or both of the photomask 40 and the wafer 31 may be relatively and appropriately moved in the longitudinal direction (in FIG. 22, ±y direction) of the plurality of line patterns 34a through 34f. For example, while the optical sources 42a through 42f of FIG. 23 disposed to correspond to the upper most part of the plurality of line patterns 34a through 34f in the y-axis direction are selectively controlled to be “on” and the remaining optical sources 42s are controlled to be “off”, the photomask 40 may be appropriately moved in the longitudinal direction (in FIG. 22, −y direction) of the plurality of line patterns 34a through 34f on the wafer 31. However, as the plurality of line patterns 34a through 34f are not to actually be formed on the wafer 31, the energy of light emitted from each of the optical sources 42a through 42f of FIG. 23 may be controlled to be low. Accordingly, a controller that selectively controls on/off of each of the plurality of the optical sources 42 may control not only on/off of the plurality of optical sources 42 but also emission energy, e.g., light emission power, of the plurality of the optical sources 42.

Referring to FIG. 24, a plurality of line patterns 36a, 36b, 36c, 36d, 36e, and 36f to be horizontally formed on the wafer 31 are illustrated. However, the patterns are not limited to the line patterns and the patterns to be formed in a longitudinal direction may be space patterns.

The optical sources 42a through 42f of FIG. 25 disposed to correspond to the left ends of the plurality of line patterns 36a through 36f to be horizontally formed on the wafer 31 in the x-axis direction are selectively controlled to be “on” and the remaining optical sources 42s of FIG. 25 are controlled to be “off”. Then, one or both of the photomask 40 and the wafer 31 may be relatively and appropriately moved in the longitudinal direction (in FIG. 24, ±x direction) of the plurality of line patterns 36a through 36f. For example, while the optical sources 42a through 42f of FIG. 25 disposed to correspond to the left ends of the plurality of line patterns 36a through 36f to be horizontally formed on the wafer 31 in the x-axis direction are selectively controlled to be “on” and the remaining optical sources 42s of FIG. 25 are controlled to be “off”, the photomask 40 may be appropriately moved in the longitudinal direction (x-axis direction in FIG. 24) of the plurality of line patterns 36a through 36f on the wafer 31. However, the plurality of line patterns 36a through 36f are not to actually be formed on the wafer 31, so that the energy of light emitted from each of the optical sources 42a through 42f of FIG. 25 may be controlled to be appropriately low. Accordingly, a controller that selectively controls on/off of the plurality of optical sources 42 may control not only on/off of the plurality of optical sources 42 but also emission energy, e.g., light emission power, of the plurality of optical sources 42.

Referring to FIG. 24, the plurality of line patterns 34a through 34f in a vertical direction and the plurality of line patterns 36a through 36f in a horizontal direction may receive exposure energy to such a degree that the plurality of line patterns 34a through 34f and the plurality of line patterns 36a through 36f are not formed on the wafer 31, whereas crossing regions D of FIG. 24 of the plurality of line patterns 34a through 34f in a vertical direction and the plurality of line patterns 36a through 36f in a horizontal direction are formed on the wafer 31.

For example, it is assumed that when minimum energy used to form a pattern on a photoresist layer on the wafer 31 is 10 (in arbitrary unit), the plurality of line patterns 34a through 34f in a vertical direction and the plurality of line patterns 36a through 36f in a horizontal direction may receive energy of 6 (in the arbitrary unit), respectively. In this case, the plurality of line patterns 34a through 34f in a vertical direction and the plurality of line patterns 36a through 36f in a horizontal direction are not formed on the wafer 31 as patterns. However, the crossing regions D of FIG. 24 of the plurality of line patterns 34a through 34f in a vertical direction and the plurality of line patterns 36a through 36f in a horizontal direction receive energy of 12 (in the arbitrary unit), thereby receiving sufficient energy for patterns to be formed on the wafer 31. For example, the patterns formed at the crossing regions D of FIG. 24 may be contact hole patterns.

FIG. 26 illustrates a plan view of first through third line patterns 37a, 37b, and 37c (or space patterns) to be vertically formed on the wafer 31, each pattern having a different line width. FIG. 27 illustrates a plan view of an exposing method used to form the pattern of FIG. 26.

Referring to FIG. 26, the first through third line patterns 37a, 37b, and 37c to be vertically formed on the wafer 31 are illustrated. However, the patterns are not limited to the line patterns, and the patterns to be formed in a longitudinal direction may be space patterns. The line patterns are widely used in a process of manufacturing a semiconductor device and may be used in, e.g., word line patterns, bit line patterns, and wiring line patterns.

The first, second, and third line patterns 37a, 37b, and 37c to be formed on the wafer 31 have line widths S1, S2, and S3 (here, S1>S2>S3), respectively. Also, the first line pattern 37a and the second line pattern 37b may be spaced apart from each other by a predetermined distance W11, and the second line pattern 37b and the third line pattern 37c may be spaced apart from each other by a predetermined distance W12.

Referring to FIGS. 26 and 27, when the distances between the first through third line patterns 37a through 37c, e.g., distances W11 and W12, smaller than the width of the substrate 41 of the photomask 40, e.g., the first width W1 in FIG. 3, a different umber of optical sources may be turned “on” in order to form the first through third line patterns 37a through 37c. For example, three optical sources 42a of FIG. 27 disposed to correspond to the upper most part of the first line pattern 37a in the y-axis direction may be turned “on”, two optical sources 42b of FIG. 27 disposed to correspond to the upper most part of the second line pattern 37b in the y-axis direction, may be turned “on”, and one optical source 42c of FIG. 27 disposed to correspond to the upper most part of the third line pattern 37c in the y-axis may be turned “on”, while the remaining optical sources 42s are controlled to be “off”. Then, one or both of the photomask 40 and the wafer 31 may be relatively and appropriately moved in the longitudinal direction (in FIG. 26, ±y direction) of the first through third line patterns 37a, 37b, and 37c. That is, as the number of optical sources increases, the photoresist layer on the wafer 31 receives a higher light energy. As such, the line width of the line patterns formed on the wafer 31 may increase. That is, as the number of optical sources is increased (42a>42b>42c), the line width of the line patterns formed on the wafer increases (S1>S2>S3).

FIG. 28 illustrates a plan view of first through third line patterns 38a, 38b, and 38c or space patterns to be horizontally formed on the wafer 31, each pattern having a different line width. FIG. 29 illustrates a plan view illustrating an exposing method used to form the pattern of FIG. 28.

Referring to FIG. 28, the first through third line patterns 38a, 38b, and 38c to be horizontally formed on the wafer 31 are illustrated. However, the patterns are not limited to the line patterns, and the patterns to be formed in a longitudinal direction may be space patterns. The line patterns are widely used in a process of manufacturing a semiconductor device and may be used in, e.g., word line patterns, bit line patterns, and wiring line patterns.

The first, second, and third line patterns 38a, 38b, and 38c to be formed on the wafer 31 have line widths S1, S2, and S3 (here, S1>S2>S3), respectively. Also, the first line pattern 38a and the second line pattern 38b are spaced apart from each other by a predetermined distance W13, and the second line pattern 38b and the third line pattern 38c are spaced apart from each other by a predetermined distance W14.

Referring to FIGS. 28 and 29, when the distance (for example, W13) between the first line pattern 38a and the second line pattern 38b and the distance (for example, W14) between the second line pattern 38b and the third line pattern 38c are smaller than the width (for example, W2 of FIG. 3) of the substrate 41 of the photomask 40 to which the plurality of optical sources 42 are attached, the optical sources 42a of FIG. 29 disposed to correspond to the left end of the first line pattern 38a in the x-axis direction, the optical sources 42b of FIG. 29 disposed to correspond to the left end of the second line pattern 38b in the x-axis direction, and the optical source 42c of FIG. 29 disposed to correspond to the left end of the third line pattern 38c in the x-axis direction are selectively controlled to be on and the remaining optical sources 42s are controlled to be off. Then, one or both of the photomask 40 and the wafer 31 may be relatively and appropriately moved in the longitudinal direction (in FIG. 28, ±x direction) of the first through third line patterns 38a, 38b, and 38c. That is, as the number of optical sources increases, the photoresist layer on the wafer 31 receives high light energy so that the line width of the line patterns formed on the wafer may increase. That is, as the number of optical sources is increased (42a>42b>42c), the line width of the line patterns formed on the wafer increases (S1>S2>S3).

As described above, one or both of the photomask and the wafer may be relatively moved. For example, a stepping method, a global scanning method, or a micro scanning method may be used to move one or both of the photomask and the wafer. Further, when one or more of the optical sources on the substrate have defects, locations of the optical sources controlled during controlling on/off of the optical sources and irradiating the optical sources may be shifted by the locations of the defective optical sources.

In the exposure apparatus according to the inventive concept, energy may be efficiently used, mass production thereof may be available, and installation costs may be reduced. Further, in the exposing method using the exposure apparatus, various forms of patterns may be formed on the wafer at low cost.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1-8. (canceled)

9. An exposing method using an exposure apparatus, the method comprising:
preparing a photomask including a plurality of optical sources attached to a substrate;
disposing the photomask adjacent a wafer;
irradiating light toward the wafer to perform exposure by selectively controlling on/off of each of the plurality of optical sources; and
forming a predetermined pattern on the wafer.

10. The method as claimed in claim 9, wherein preparing the photomask includes forming each of the plurality of optical sources as a light emitting diode (LED) or as a laser diode.

11. The method as claimed in claim 9, wherein forming the predetermined pattern includes forming contact hole patterns or through silicon via (TSV) patterns on the wafer.

12. The method as claimed in claim 11, wherein irradiating the light includes selectively controlling on/off timing of the optical sources, such that optical sources set as “on” correspond to the contact hole patterns or the TSV patterns to be formed in the wafer.

13. The method as claimed in claim 9, wherein forming the predetermined pattern includes forming line patterns or space patterns on the wafer.

14. The method as claimed in claim 13, wherein irradiating the light includes:
selectively controlling on/off timing of the optical sources, such that optical sources set as “on” correspond to the line patterns or the space patterns to be formed in the wafer; and
relatively moving at least one of the photomask and the wafer in a longitudinal direction of the line patterns or the space patterns.

15. The method as claimed in claim 9, wherein forming the predetermined pattern includes forming line or space patterns having different widths.

16. The method as claimed in claim 15, wherein irradiating the light includes:
selectively controlling on/off timing of the optical sources, such that optical sources set as “on” correspond to the line or space patterns to be formed in the wafer, and such that a larger number of optical sources corresponds to a wider pattern; and
relatively moving at least one of the photomask and the wafer in a longitudinal direction of the line or space patterns.

17. The method as claimed in claim 9, wherein irradiating the light includes:
controlling the on/off of each of the optical sources of the photomask to correspond to the predetermined pattern on the wafer; and
relatively moving at least one of the photomask and the wafer.

18. The method as claimed in claim 17, wherein the relative moving includes at least one of a stepping method, a global scanning method, or a micro scanning method.

19. The method as claimed in claim 17, wherein controlling the on/off of the optical sources includes shifting defective optical sources to align operational optical sources with the predetermined pattern.

20. An exposing method using an exposure apparatus, the method comprising:
preparing a photomask including a plurality of optical sources on a substrate;
disposing the photomask relative to a wafer, such that light from the photomask is incident on the wafer; and
selectively controlling light emission of each of the plurality of optical sources, such that light emitted from the photomask is incident only on regions of the wafer to be patterned.
